(19) United States
(12) Patent Application Publication
(10) Pub. No.: US 2011/0037485 A1
(43) Pub. Date: Feb. 17, 2011

(54) COVERING AND SEALING FILM FOR A PACK AND A METHOD FOR DETERMINING THE OPENING STATE OF A PACK

(75) Inventor: Michael Kiy, Winterthur (CH)

Correspondence Address: RATNERPRESTIA, P.O. BOX 980, VALLEY FORGE, PA, 19482, US

(73) Assignee: AMCOR FLEXIBLES KREUZLINGEN LTD., Kreuzlingen (CH)

(21) Appl. No.: 12/990,015

(22) PCT Filed: Apr. 16, 2009
(86) PCT No.: PCT/EP2009/002777

§ 371 Date: Oct. 28, 2010

(30) Foreign Application Priority Data
Apr. 28, 2008 (EP) 08008088.8

(51) Int. Cl. G01R 27/28; H01B 5/00; H05K 1/00; G01R 27/26

(52) U.S. Cl. 324/651; 174/126.1; 174/250; 324/658

(57) ABSTRACT

The invention concerns a covering and/or sealing film for a pack, in particular a blister pack, configured to seal at least one filling product chamber and allow opening access to the filling product chamber by separation and/or tearing, wherein the film, in particular in the area of the filling product chamber, has a predetermined electrical conductance property (C₁₄) which can be contacted for electronic analysis and as a reaction to separation or tearing undergoes an evaluatable change, wherein the film, at least in sections, has a capacitatively active, contactable layer structure, the electrical capacitance of which undergoes a change by the tearing or separation.

The present invention concerns a covering and/or sealing film for a pack, in particular a blister pack, according to the preamble of the main claim. Furthermore, the present invention concerns a method for determining the opening state of a pack which is closed by means of a covering and/or sealing film, and the use of a covering and/or sealing film.

Such a generic covering and/or sealing film is known generally from the prior art, for example in the form of a medicament blister pack in which the sealing film carries an electrically conductive track which is allocated to a filling product chamber so that on (manual) access to the medicament in the filling product chamber, the electrically conductive track is destroyed and thus by electronic analysis of the conductance behaviour of the track, it can be established whether the filling product chamber has been opened. EP 0 972 507 A1 discloses such a known covering or sealing film wherein here a multiplicity of filling product chambers and consequently a more complex conductor track structure is described, which is analysed electronically in relation to an overall ohmic resistance; according to this disclosure from the prior art, local tearing or separation leads to an interruption of a specific conductor track (with resistance), with a corresponding effect on the (electronically analysed) overall resistance of the conductor track arrangement.

However, because of its principle such a known procedure, in particular with a multiplicity of filling product chambers to be sealed by means of a covering or sealing film, is not without problems: for example if the ohmic resistances (as electrical conductance properties in the known prior art) are connected and analysed in the manner of an electrical series circuit, opening just one filling product chamber with corresponding separation of the connection interrupts the measurement current circuit so that later further removals from other filling product chambers in the series circuit can no longer be detected. In contrast individual detection of this switching behaviour generated by separation (on/off depending on separation and opening state) would require a separate conductor track guide to each individual filling chamber, which is impractical in blister packs with a high number of filling product chambers. If however, as in the case of EP 0 972 507 A1, a total resistance of the conductor track structure is detected and analysed, with the (necessary, see above) parallel connection of each conductor track section offering individual resistance Ri of a respective filling product chamber, this would be accompanied by a reversal in the resulting total resistance. This in turn has the consequence that substantial complexity is required in the electronic analysis in order to reliably detect the separation (and therefore opening) of an individual conductor in the case of a multiplicity of corresponding parallel-connected individual conductors Ri with ohmic resistance.

The object of the present invention is therefore to provide an alternative process for the electronic detection of the opening state of a pack which is closed by means of a covering and/or sealing film, and a corresponding covering or sealing film which in relation to its properties of use and analysis allows reliable detection of opening access to a filling product chamber even in the case of a multiplicity of such chambers, which at the same time can be produced and contacted at low cost, in particular while being suitable for mass production.

The object is achieved by the covering and/or sealing film with the features of the main claim, furthermore the use of such a film according to the independent claim 11 and the method for determining the opening state of a package closed by means of a covering and/or sealing film according to the independent claim 12. Advantageous refinements of the invention are described in the subclaims.

Advantageously, according to the invention the film at least in sections has a capacitatively active layer structure, the electrical capacitance of which (as an electrical conductance property in the sense of the present invention) is changed by separation or tearing on (manual) access to a filling product chamber concerned. Thus in contrast to the prior art according to EP 0 972 507 A1 for example, it is not the ohmic resistance of a conductor track structure allocated to a filling product chamber or its change as a reaction to separation or tearing which is evaluated, rather the capacitative properties of the film (or structure formed thereon) and its change on access to the filling product chamber are established and evaluated. Such a procedure admittedly appears to lead to apparently higher production costs, because in contrast to an ohmic measurement method requiring merely one conductor track guided on a substrate, at least in the relevant sections a three-layer structure is required comprising an electrode pair with a dielectric lying in between; according to the present invention, however, this is compensated by the fact of substantially improved analysis capacity and substantially more flexibility in use, in particular in connection with further peripheral electronics provided on the covering or sealing film in preferred refinements of the invention. Thus namely the parallel connection of individual capacitances according to the present invention which are allocated to the filling product chambers are added together, so that for analysis electronics evaluating the entire capacitance, according to the opening state a clear and evenly stepped total capacitance signal is present (wherein in principle the present invention also includes the possibility of partial or local separation of a capacitative layer sealing a multiplicity of filling product chambers and to this extent due to the reduction of the capacitatively active area, corresponding to the parallel circuit described, a capacitance reduction occurs).

The present invention also includes forming the capacitatively active section, preferably provided, and allocated to a filling product chamber directly to cover or close the filling product chamber, and evaluating its capacitance change as opening status detection, and separating or tearing a supply line to such a capacitance for opening status detection so that then the capacitatively active section concerned no longer contributes to forming the entire capacitance (by parallel connection). In this case it is also advantageous to create on or in the covering or sealing film merely a simple conductor track structure to which a multiplicity of capacitatively active sections allocated to the filling product chambers can be electrically connected in parallel (and thus cumulative in relation to their entire capacitance).

The implementation of the present invention also brings numerous advantages in process technology; according to preferred refinements, firstly in relation to series production it is favourable to apply at least one layer constituting an electrode onto a substrate (which can itself in turn serve as a dielectric) by means of vapour deposition, lamination or other methods of application of a metal; in addition or alternatively a conductive layer can be applied by lacquering with (correspondingly conductive) lacquer, by application of a conductive polymer or similar, and like the dielectric layer can be generated by means of insulating lacquer layer or by chemical treatment of an adjacent electrode layer (e.g. by oxidation of a surface thereof). In particular the latter variant also offers the advantage that in a manner which is elegant from a process technical aspect and also electrotechnically optimised, an effective surface enlargement of a metal layer (serving as a first electrode) can be achieved by etching or similar chemical or electrochemical measures; subsequent oxidation of this enlarged area metal layer (e.g. as aluminium layer into aluminium oxide) generates the correspondingly large area dielectric layer, and subsequent vapour deposition of the dielectric layer with conductive material provides the counter electrode. In this way a large effective capacitance surface can be produced on an optimised film surface which is also suitable for large scale economic production.

By using the electrical conductance property as an electrical capacitance according to the invention, it is also advantageously possible for this capacitance (in particular in the case of an electrical capacitance which is maximised by the measures described above) to serve as a power supply for peripheral electronics which are arranged preferably in the covering or sealing film, wherein suitable coupling allows the capacitance to be supplied (also wirelessly) with corresponding charge. Not least the possibility of providing the peripheral electronics with analysis electronics (e.g. to evaluate the opening status) and according to a refinement, forming additional RFID or similar high frequency transmission technology directly by suitable conductor tracks on the covering or sealing film, brings maximum flexibility and usability of the present invention for a multiplicity of areas of application. In this context it is particularly preferred in a refinement to allow the electrical capacitance, which is changed by separation or tearing, of an RC and/or oscillation circuit structure to act such that this leads directly to a modulation or influencing of an externally (and preferably wirelessly) sampled signal (opening state signal).

Finally, the present invention achieves in a surprisingly simple and elegant manner not only a way of creating reliably and precisely analysable opening status detection for a multiplicity of filling product chambers to be sealed with the covering or sealing film, but the capacitative approach according to the invention offers ideal possibilities for connecting the opening status detection according to the invention with (preferably high frequency or wireless) peripheral electronic components which for example allow an RFID functionality with minimum expense and using the same film as a carrier, and can also potentially be supplied with operating voltage by the capacitance.

Further advantages, features and details of the invention arise from the description below of preferred embodiments and with reference to the drawings. These show:

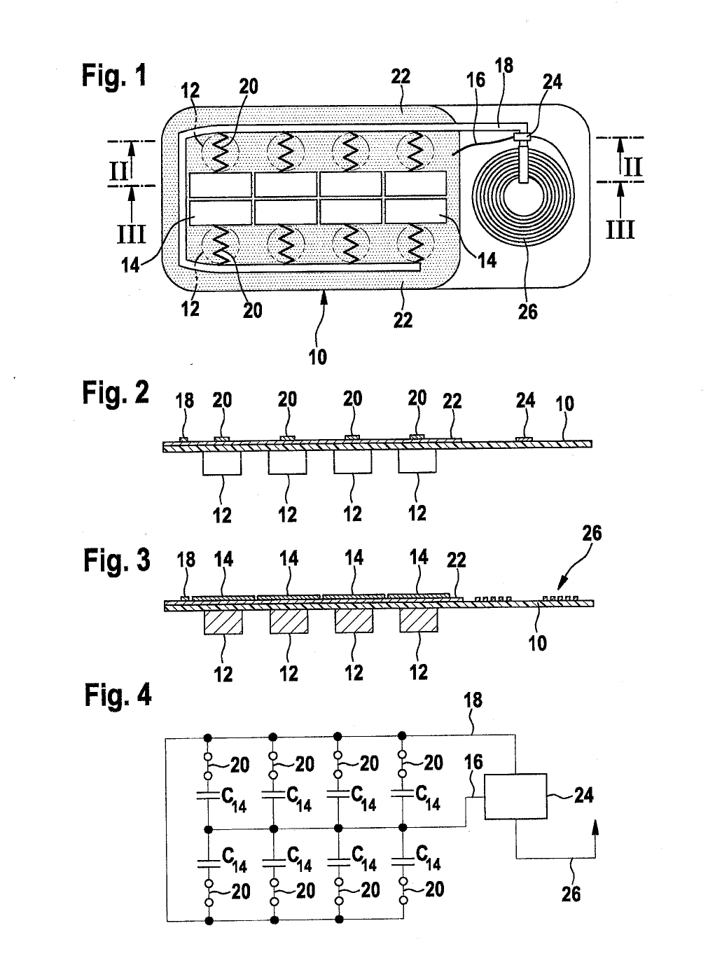

FIG. 1 a top view onto a blister pack which is closed by means of a covering or sealing film with additional peripheral electronics provided on the film according to a preferred embodiment of the present invention;

FIG. 2 a sectional view along the cut line II-II in FIG. 1;

FIG. 3 a sectional view along the cut line III-III in FIG. 1, and

FIG. 4 a circuit diagram of the electronic or functional components provided in the embodiment example of FIGS. 1 to 3.

FIG. 1 shows in top view a first embodiment example of the invention wherein the covering film 10 shown is provided to close a total of eight filling product chambers 12 in the manner of a blister carrier unit, otherwise already known. The film 10 is itself made from an insulating material e.g. a plastic film 10 carried on a section of an aluminium film 22 which in turn is coated with an insulating lacquer. The aluminium film 22 thus forms a first large area electrode of the device as a counter electrode for eight second electrode sections 14 which are each allocated to a filling product chamber 12, and is contacted by way of a first supply line 16. The second electrodes (electrode surfaces) 14 are contacted in the manner shown in FIG. 1 in a U shape by a second supply line 18 and by meandering conductor pieces 20 so that in the manner shown in FIG. 4, a parallel circuit is produced of the individual capacitances C₁₄ corresponding to a capacitance formed in each case by an electrode surface 14 in relation to the (coated) aluminium film 22. In concrete terms the second supply line 18, the supply lines 20 and the electrode surfaces 14 are produced as conductive sections (e.g. produced by means of conductive paint or conductive polymer) on the lacquer serving as a dielectric on the coated aluminium foil 22.

In the embodiment example shown each of the surfaces 14 is approximately 2 cm² large, wherein the lacquer used to produce the insulating intermediate layer on the conductive layer 22 (dielectric) is typically applied in a lacquer thickness of 2 μm and has a dielectric constant εᵣ of 3. This leads to a capacitance C₁₄ of the order of around 27 nF, which, depending on the opening state of the filling product chambers (in the case of opening the blister pack, the supply line 20 is separated) contributes to the parallel circuit of all capacitances present at the two-terminal network 16, 18 or is disconnected from this by the separation.

The opening detection unit which is formed from the units 12 to 22, which in regard to the terminals 16 or 18 constitutes the two-terminal network, and as described has a total capacitance formed from addition of the individual capacitances C₁₄, in the embodiment example described is analysed by an integrated unit 24 which is provided as a chip which also has an RFID functionality and as a function of the total capacitance present between terminals 16 and 18 modulates the signal which can be evaluated or emitted externally by way of the RFID antenna 26 which is indicated symbolically.

The unit 24 which is constituted in the embodiment example shown by means of an integrated circuit unit, is preferably also configured so that it can be supplied with operating voltage by way of the parallel circuit of capacitances C₁₄.

In use of the device shown, a user now takes the filling product, e.g. a tablet, from the respective chamber 12 in the known manner by locally cutting or tearing the covering film 10 in the area of the chamber 12 concerned, with the result that the connecting conductor piece 20 is separated. As a result, indicated by the symbolic switch unit in the circuit diagram in FIG. 4, the connection to the capacitor concerned is electrically separated (opened) so that this capacitor no longer contributes to the total capacitance. Accordingly, the total capacitance is reduced by the contribution of the capacitance concerned, where in the example described of the parallel connection of the capacitances, this takes place as a subtraction of the capacitance value.

The capacitance thus reduced is present at the analysis unit 24 by means of terminals 16, 18, and—actively or passively and in another known manner by means of RFID technology or another, preferably wireless route—can be transmitted to an external communication partner for further processing.

The present invention is not restricted to the embodiment example shown, in particular an (almost arbitrary) structure with other capacitance configurations is possible, in particular also an individual capacitance covering the whole surface which then covers several filling chambers and on removal is partially broken. Also it is not necessary to provide an analysis on the film in the form of the analysis unit 24, rather again in any sensible manner a two-pole or multi-pole contacting of the circuit of the individual capacitances can take place on, under or at the side of the film in the manner required.

1. A covering and/or sealing film for a pack, configured to seal at least one filling product chamber and to allow opening access to the filling product chamber by separation and/or tearing, wherein the film has a predetermined electroconductive property (C₁₄) which can be contacted for electronic analysis and undergoes an analysable change as a reaction to separation or tearing, wherein the film at least in sections has a capacitatively active contactable layer structure, the electrical capacitance of which undergoes a change on tearing or separation.

2. A film according to claim 1 wherein the film is formed to close a multiplicity of filling product chambers, a capacitatively active section of the film is allocated to a multiplicity of filling product chambers and an analysable electrical total capacitance of the film includes a capacitive parallel connection of the sections.

3. A film according to claim 2 wherein the capacitatively active sections are contacted and/or connected together by an electrical contact and/or conductor track structure which is formed by means of the film.

4. A film according to claim 2 wherein the capacitatively active sections are provided so the separation or tearing causes the interruption of an electrical supply line to an allocated capacitatively active section.

5. A film according to claim 1 wherein the capacitatively active layer structure has an electrically conductive electrode layer and a dielectric layer formed by an applied insulating lacquer or by chemical treatment of the electrode layer.

6. A film according to claim 1 wherein the capacitatively active layer structure has an electrode layer which is formed on the dielectric layer by coating with electrically conductive lacquer or an electrically conductive polymer and/or by application of a metal layer.

7. A film according to claim 1 wherein the capacitatively active layer structure, at least in sections, has an electrode layer pair whose capacitatively active metallic surface is enlarged by a chemical or electrochemical treatment.

8. A film according to claim 1 wherein the sealing film is formed for holding and/or application of analysis and/or peripheral electronics contacting the capacitatively active layer structure.

9. A film according to claim 8 wherein through the capacitatively active layer structure, the peripheral electronics receive a power supply and/or comprise an electronic oscillation circuit structure.

10. A film according to claim 8 wherein the peripheral electronics are formed as an RFID circuit which is modulated and/or controlled by the change.

11. A method comprising using the covering and/or sealing film according to claim 1 to seal a blister pack which is fitted with the electronic analysis means contacting the capacitatively active layer structure, in order to detect an in particular partial opening state of the blister pack and preferably make this accessible for further electronic processing.

12. A method of determining the opening state of a pack, which is closed by means of a covering and/or sealing film according to claim 1, the method comprising the steps:
determining an electrical capacitance of the covering and/or sealing film, and
establishing an opening state of the pack if the electrical capacitance deviates from a predetermined comparison and/or threshold value.

13. A method according to claim 12 wherein the determination of the electrical capacitance value includes the analysis of an oscillation and/or frequency behaviour of an oscillation circuit and/or RC element, in which a capacitatively active layer structure acts electrically on the covering and/or sealing film.

14. A method according to claim 12, comprising the step of transmitting an opening status signal.

15. A film according to claim 1 wherein the film has a predetermined electroconductive property (C14) in the area of the filling product chamber.

16. A film according to claim 5 wherein the dielectric layer is formed by oxidation of the electrode layer.

17. A film according to claim 6 wherein the electrode layer is formed on the dielectric layer by vapour deposition or lamination of the metal layer.

18. A film according to claim 8 wherein the peripheral electronics comprise a high frequency electronic oscillation circuit structure.

19. A method according to claim 14 wherein the opening status signal is transmitted by a high frequency coil structure which is formed with or on the covering and/or sealing film.
